(19) United States
(12) Patent Application Publication
(10) Pub. No.: US 2006/0171206 A1
(43) Pub. Date: Aug. 3, 2006

(54) NON-VOLATILE MEMORY AND FABRICATING METHOD AND OPERATING METHOD THEREOF

(76) Inventors: Wei-Zhe Wong, Tainan City (TW); Ching-Sung Yang, Hsinchu City (TW); Chih-Chen Cho, Taipei City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/162,158

(22) Filed: Aug. 31, 2005

(30) Foreign Application Priority Data
Feb. 3, 2005 (TW) 94103337

(51) Int. Cl. G11C 16/04

(52) U.S. Cl. 365/185.28

(57) ABSTRACT

A non-volatile memory is provided. A well is disposed in a substrate and a shallow well is disposed inside the well. At least two stack gate structures are disposed on the substrate. Drain regions are disposed in the shallow well outside the stack gate structures. An auxiliary gate layer is disposed on the substrate between the two stack gate structures. The auxiliary gate layer extends down passing through a portion of the substrate. A gate dielectric layer is disposed between the auxiliary gate layer and the substrate and between the auxiliary gate layer and the stack gate structures. A conductive plug is disposed on the substrate. The conductive plug extends downward to connect with the shallow well and the drain region therein.

### CROSS-REFERENCE TO RELATED APPLICATION

This application claims the priority benefit of Taiwan application serial no. 94103337, filed on Feb. 3, 2005. All disclosure of the Taiwan application is incorporated herein by reference.

### BACKGROUND OF THE INVENTION

1. Field of the Invention

The present invention relates to a memory device and fabricating method and operating method thereof. More particularly, the present invention relates to a non-volatile memory and fabricating method and operating method thereof.

2. Description of the Related Art

Non-volatile memory is a type of memory that has been widely used inside personal computer systems and electron equipment. Data can be stored, read out or erased from the non-volatile memory countless number of times and any stored data is retained even after power supplying the devices is cut off.

Typically, a non-volatile memory has floating gate and control gate fabricated using doped polysilicon. Top program data into or erase data from the non-volatile memory, a suitable voltage is applied to the source region, the drain region and the control gate so that electrons are injected into the floating gate or electrons are pulled out from the floating gate. In general, the mode for injecting electric charges into the non-volatile memory can be categorized into channel hot electron injection (CHEI) and F-N (Fowler-Nordheim) tunneling. Furthermore, the mode for programming data into or erasing data from the non-volatile memory device changes according to the way the electric charges are injected or pulled.

FIG. 1 is a schematic cross-sectional view of a conventional non-volatile memory. As shown in FIG. 1, the non-volatile memory includes an n-type substrate 100, a p-type deep well 102, an n-type well 104, stack gate structures 106a and 106b, n-type source regions 108a, n-type drain regions 108b, p-type shallow doped regions 109, p-type pocket doped regions 110 and conductive plugs 112. The p-type deep well 102 is disposed in the substrate 100 and the n-type well 104 is disposed within the p-type deep well 102. The stack gate structures 106a and 106b are disposed on the substrate 100. Each stack gate structure 106a, 106b includes a tunneling layer 114, a floating gate layer 116, an inter-gate dielectric layer 118, a control gate layer 120 and a mask layer 122 sequentially stacked on the substrate 100. Furthermore, spacers 124 are formed on the sidewalls of the stack gate structures 106a and 106b. The n-type source region 108a is disposed between the two stack gate structures 106a, 106b in the n-type well region 104 and the p-type shallow doped regions 109. The p-type shallow doped regions 109 are disposed within the n-type well region 104 adjacent to the surface of the substrate 100. The p-type pocket doped regions 110 are disposed in the n-type well region 104 outside the stack gate structures 106a and 106b and extend into the region underneath the stack gate structures 106a and 106b adjacent to the p-type shallow doped regions 109. The n-type drain region 108b are disposed in the p-type pocket doped regions 110 outside the stack gate structures 106a and 106b. The conductive plugs 112 are disposed on the substrate 100 and extend downward to pass through the n-type drain region 108b and connect with a portion of the p-type pocket doped region 110.

To program one of the memory cells in the aforementioned non-volatile memory, for example, the main memory cell such as the stack gate structure 106a or the stack gate structure 106b, a voltage is applied to the source region, the drain region and the control gate layer. However, the control gate layer and the source region of the memory cell are connected to the control gate layer and the source region of an adjacent memory cell. In other words, the two memory cells use the same word line and source line. Thus, when programming a selected memory cell, other non-selected memory cells chained to the same word line will be interfered by the applied voltage. Consequently, the reliability of the memory device can be affected.

Furthermore, in the process of programming the non-volatile memory, the presence of the source region and the closeness between the control gate and the source region can easily lead to current leakage problem in the device.

### SUMMARY OF THE INVENTION

Accordingly, at least one objective of the present invention is to provide a non-volatile memory capable of resolving the problem of interfering with an adjacent memory cell when a voltage is applied to program data into single memory cell in a conventional programming operation.

At least a second objective of the present invention is to provide a method of fabricating a non-volatile memory capable of resolving the problem of interfering with an adjacent memory cell when a voltage is applied to program data into single memory cell in a conventional programming operation.

At least a third objective of the present invention is to provide a method of operating a non-volatile memory capable of resolving the problem of interfering with an adjacent memory cell when a voltage is applied to program data into single memory cell.

To achieve these and other advantages and in accordance with the purpose of the invention, as embodied and broadly described herein, the invention provides a non-volatile memory. The non-volatile memory mainly includes a substrate, a first conductive type well, a second conductive type shallow well, a pair of stack gate structures, two first conductive type drain regions, an auxiliary gate layer, a gate dielectric layer and at least two conductive plugs. The first conductive type well is disposed in the substrate and the second conductive type shallow well is disposed within the first conductive type well. Each stack gate structure includes at least a floating gate layer and a control gate layer above the floating ate layer. The first conductive type drain regions are disposed in the second conductive type shallow well outside the pair of the stack gate structures. The auxiliary gate layer is disposed on the substrate between the two stack gate structures. Furthermore, the auxiliary gate layer extends downward to pass through a portion of the substrate such that the bottom of the auxiliary gate layer is beneath the bottom of the second conductive type shallow well. The gate dielectric layer is disposed at least between the auxiliary gate layer and the substrate and between the auxiliary gate layer and the stack gate structures. The two conductive plugs are disposed on the substrate and extend downward to connect with the second conductive type shallow well and the drain region therein.

According to aforementioned non-volatile memory in the preferred embodiment of the present invention, the substrate is a first conductive type substrate.

According to the aforementioned non-volatile memory in the preferred embodiment of the present invention, the non-volatile memory further includes a second conductive type deep well disposed in the substrate such that the first conductive type well is located within the second conductive type deep well.

According to aforementioned non-volatile memory in the preferred embodiment of the present invention, each stack gate structure further includes a tunneling layer, a floating gate layer, an inter-gate dielectric layer and a control gate sequentially formed on the substrate.

According to aforementioned non-volatile memory in the preferred embodiment of the present invention, the auxiliary gate layer, the floating gate layer and the control gate layer are fabricated using polysilicon or doped polysilicon.

According to aforementioned non-volatile memory in the preferred embodiment of the present invention, the gate dielectric layer is fabricated using silicon oxide, for example.

According to aforementioned non-volatile memory in the preferred embodiment of the present invention, the non-volatile memory is a NOR type memory array.

According to aforementioned non-volatile memory in the preferred embodiment of the present invention, the first conductive type is n-type and the second conductive type is p-type.

According to aforementioned non-volatile memory in the preferred embodiment of the present invention, the non-volatile memory further includes a plurality of isolation structures disposed in the substrate to define an active region. Furthermore, the pair of stack gate structures is disposed on the substrate inside the active region such that each stack gate structure is located beside the isolation structures. In addition, the auxiliary gate layer is disposed between two adjacent isolation structures.

The auxiliary gate layer of the non-volatile memory in the present invention can be used to trigger the source region. Hence, a suitable auxiliary gate voltage can be used to prevent the source from triggering and thus resolving device current leakage problem in the conventional programming operation. In addition, the selection of a particular memory cell has no effect on adjacent memory cell in a programming operation so that the reliability of the device is improved.

The present invention also provides a method of fabricating a non-volatile memory. First, a substrate is provided. Then, a first conductive type well is formed in the substrate. Thereafter, a second conductive type shallow well is formed inside the first conductive type well. After that, at least a pair of stack gate structures is formed on the substrate. Each stack gate structure includes at least a floating gate layer and a control gate layer above the floating gate layer. A first conductive type drain region is formed in the second conductive type shallow well outside the stack gate structures. Then, a portion of the substrate between the two stack gate structures is removed to form an opening in the substrate. The bottom of the opening is below the bottom of the second conductive type shallow well. Thereafter, a gate dielectric layer is formed on the stack gate structures and the exposed substrate. An auxiliary gate layer is formed on the gate dielectric layer between the two stack gate structures. The auxiliary gate layer fills up the opening. A dielectric layer is formed over the substrate to cover the gate dielectric layer and the auxiliary gate layer. At least two contact openings are formed in the dielectric layer such that each contact opening exposes the drain region and a portion of the second conductive type shallow well. Subsequently, a conductive plug is formed inside each contact opening.

According to the aforementioned method of fabricating a non-volatile memory in the preferred embodiment of the present invention, the step of removing a portion of the substrate between the two stack gate structures includes performing a self-aligned etching process.

According to the aforementioned method of fabricating a non-volatile memory in the preferred embodiment of the present invention, the substrate is a first conductive type substrate, for example.

According to the aforementioned method of fabricating a non-volatile memory in the preferred embodiment of the present invention, after providing the substrate but before forming the first conductive type well, further includes forming a second conductive type deep well in the substrate such that the first conductive type well is located within the second conductive type deep well.

According to the aforementioned method of fabricating a non-volatile memory in the preferred embodiment of the present invention, each stack gate structure further includes a tunneling layer, a floating gate layer, an inter-gate dielectric layer and a control gate layer sequentially formed on the substrate.

According to the aforementioned method of fabricating a non-volatile memory in the preferred embodiment of the present invention, the auxiliary gate layer, the floating gate layer and the control gate layer are fabricated using polysilicon or doped polysilicon.

According to the aforementioned method of fabricating a non-volatile memory in the preferred embodiment of the present invention, the conductive plugs are connected to the drain region and the second conductive type shallow well, for example.

According to the aforementioned method of fabricating a non-volatile memory in the preferred embodiment of the present invention, the first conductive type is n-type and the second conductive type is p-type.

According to the aforementioned method of fabricating a non-volatile memory in the preferred embodiment of the present invention, after providing the substrate but before forming the first conductive type well, further includes forming a plurality of isolation structures to define an active region. The stack gate structures are formed on the substrate within the active region such that the stack gate structures are disposed beside the isolation structures. In addition, the auxiliary gate structure is formed between two adjacent isolation structures.

The auxiliary gate layer of the non-volatile memory in the present invention can be used to trigger the source region. Hence, a suitable auxiliary gate voltage can be used to prevent the source from triggering and thus resolving device current leakage problem in the conventional programming operation. Furthermore, the method of fabricating the non-volatile memory in the present invention is compatible with the conventional fabrication method. Thus, there is no need to acquire additional equipment.

The present invention also provides a method of operating a non-volatile memory. The method is suitable for operating the aforementioned type of non-volatile memory. First, one in the pair of the stack gate structures is selected as a selected memory cell. In a subsequent programming operation, a first voltage is applied to the control gate layer of the selected memory cell and a second voltage is applied to the drain region beside the selected memory cell and the first conductive type well. In addition, a third voltage is applied to the auxiliary gate layer and the second conductive type deep region. The first voltage is between −5V to −15V, the second voltage is between 1V to 10V and the third voltage is about 0V, for example.

According to the aforementioned method of operating the non-volatile memory, the method also includes performing an erasing operation. To carry out an erasing operation, a fourth voltage is applied to the control gate of the selected memory cell and a fifth voltage is applied to the first conductive type well and the second conductive type deep well. Moreover, the drain region beside the selected memory cell and the auxiliary gate layer are set into a floating state to remove the data within the selected memory cell. The fourth voltage is between 5V to 15V and the fifth voltage is between −5V to −15V, for example.

According to the aforementioned method of operating the non-volatile memory, the method also includes performing a reading operation. To carry out a reading operation, a sixth voltage is applied to the control gate and the auxiliary gate layer of the selected memory cell and a seventh voltage is applied to the first conductive type well. Moreover, an eighth voltage is applied to the drain region beside the selected memory cell and the second conductive type deep well to read the data from the memory cell. The sixth voltage is between 1V to 10V, the seventh voltage is between 1V to 10V and the eighth voltage is about 0V, for example.

The non-volatile memory in the present can use the auxiliary gate layer to trigger the source. Hence, a suitable auxiliary gate voltage can be used to prevent the triggering of the source in a programming operation and thus resolving the device current leakage problem. In addition, the selection of the desired memory cell has no effect on adjacent memory cells so that the reliability of the device is improved.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a conventional non-volatile memory.

FIG. 2 is a top view of a non-volatile memory according to one preferred embodiment of the present invention.

FIG. 3A is a schematic cross-sectional view of the non-volatile memory along I-I′ (the X direction) in FIG. 2.

FIG. 3B is a schematic cross-sectional view of the non-volatile memory along II-II′ (the Y direction) in FIG. 2.

FIG. 4 is a schematic cross-sectional view of a non-volatile memory according to another preferred embodiment of the present invention.

FIG. 5A through 5D are schematic cross-sectional views along line I-I′ (the X direction) in FIG. 2 showing the steps for fabricating a non-volatile memory.

FIG. 6A through 6D are schematic cross-sectional views along line II-II′ (the Y direction) in FIG. 2 showing the steps for fabricating a non-volatile memory.

FIG. 7 is an equivalent circuit diagram of a NOR type memory cell array according to the present invention.

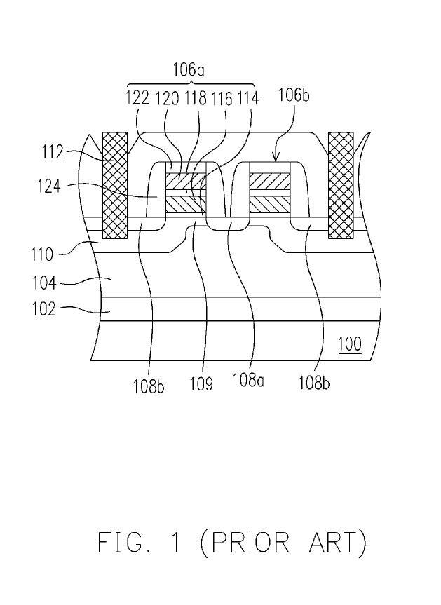

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

In the following embodiment, the first conductive type is an n-doped material and the second conductive type is a p-doped material. As anyone familiar with semiconductor fabrication may notice, the doping state for the first conductive type and the second conductive type can be interchanged. Hence, an explanation for an embodiment using materials having exactly the opposite doping states is omitted. In addition, in the following embodiment, a NOR type non-volatile memory that uses the same auxiliary gate layer is selected to described the present invention.

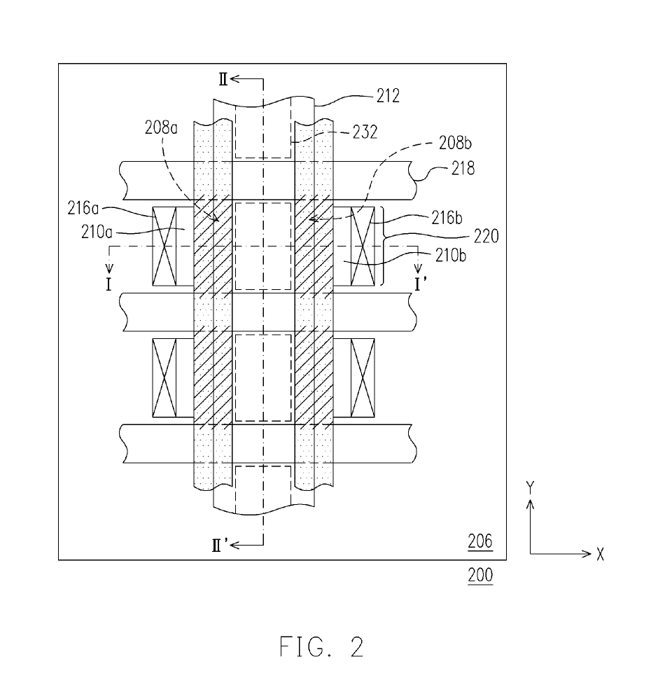

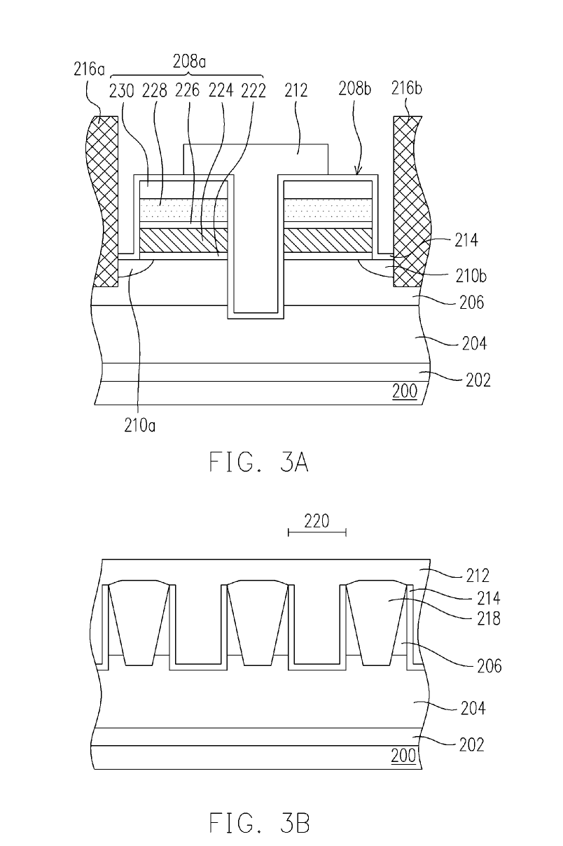

FIG. 2 is a top view of a non-volatile memory according to one preferred embodiment of the present invention. FIG. 3A is a schematic cross-sectional view of the non-volatile memory along I-I′ (the X direction) in FIG. 2. FIG. 3B is a schematic cross-sectional view of the non-volatile memory along II-II′ (the Y direction) in FIG. 2. As shown in FIGS. 2, 3A and 3B, the non-volatile memory of the present invention includes an n-type substrate 200, a p-type deep well 202, an n-type well 204, a p-type shallow well 206, a pair of stack gate structures 208a, 208b, two n-type drain regions 210a, 210b, an auxiliary gate layer 212, a gate dielectric layer 214, at least two conductive plugs 216a, 216b and at least two isolation structures 218.

The two isolation structures 218 are disposed in the n-type substrate 200 to define an active region 220. Furthermore, the p-type deep well 202 is disposed in the substrate 200 and the n-type well 204 is disposed within the p-type deep well 202. The p-type shallow region 206 is disposed within the n-type well 204.

The stack gate structures 208a , 208b are disposed on the substrate 200 within the active region 220. Furthermore, the stack gate structures 208a and 208b are located beside the respective isolation structures 218. Each of the stack gate structures 208a, 208b includes a tunneling layer 222, a floating gate layer 224, an inter-gate dielectric layer 226 and a control gate 228 sequentially formed on the substrate 200. In one embodiment, the stack gate structures 208a, 208b further include a mask layer 230 disposed on their respective control gate layer 228. The floating gate layer 224 is fabricated using polysilicon, doped polysilicon or other suitable material, for example. Similarly, the control gate layer 228 is fabricated using polysilicon, doped polysilicon or other suitable material, for example.

The n-type drain regions 210a, 210b are disposed in the p-type shallow well 206 outside the pair of stack gate structures 208a, 208b.

In addition, the auxiliary gate layer 212 is disposed on the substrate 200 between the two stack gate structures 208a and 208b and adjacent to the two isolation structures 218. The auxiliary gate layer 212 extends in a downward direction to pass through a portion of the substrate 200 such that the bottom of the auxiliary gate layer 212 is below the bottom of the p-type shallow well 206. The auxiliary gate layer 212 is fabricated using polysilicon, doped polysilicon or other suitable material, for example.

The gate dielectric layer 214 is disposed at least between the auxiliary gate layer 212 and the substrate 200 and between the auxiliary gate layer 212 and the stack gate structures 208a, 208b. The gate dielectric layer 214 is fabricated using silicon oxide, for example. The conductive plugs 216a, 216b are disposed on the substrate 200. Furthermore, the conductive plug 216a extends down to connect with the drain region 210a and the p-type shallow well 206 and the conductive plug 216b extends down to connect with the drain region 210b and the p-type shallow well 206.

The auxiliary gate layer of the non-volatile memory in the present invention can be used to trigger the source region. Hence, a suitable auxiliary gate voltage can be used to prevent the source from triggering and thus resolving device current leakage problem in the conventional programming operation. In addition, the process of selecting a particular memory cell will not affect an adjacent memory cell during a programming operation. Thus, the reliability of the device is improved.

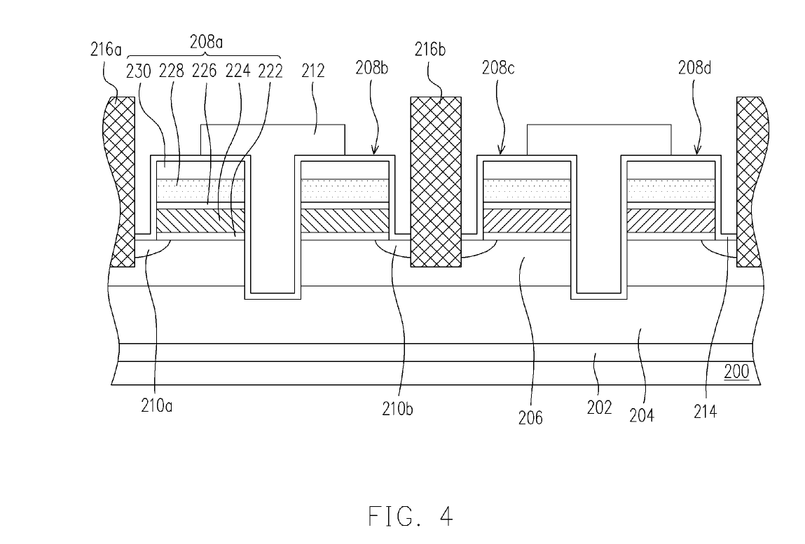

In the aforementioned embodiment, a non-volatile memory having just two stack gate structures 208a, 208b is used in the illustration. In other words, the non-volatile memory has two memory cells only. However, the present invention is not limited as such. The memory of the present invention may include four stack gate structures 208a, 208b, 208c and 208d as shown in FIG. 4 (altogether four memory cells) or more stack gate structures (more memory cells). If two memory cells form a group, then the stack gate structures 208a and 208b form a group and the stack gate structures 208c and 208d form another group. Furthermore, each group of stack gate structures shares a single drain region and a conductive plug.

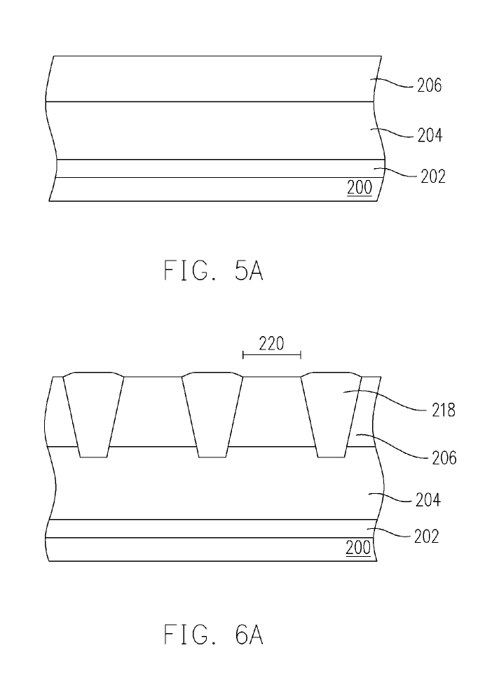

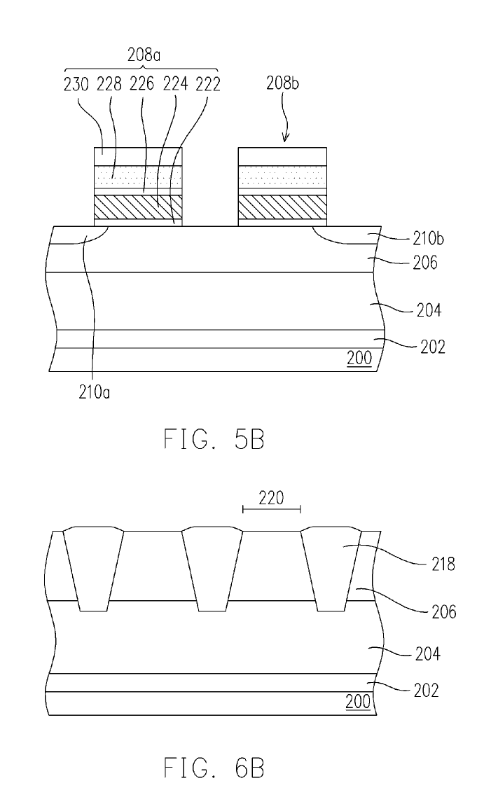

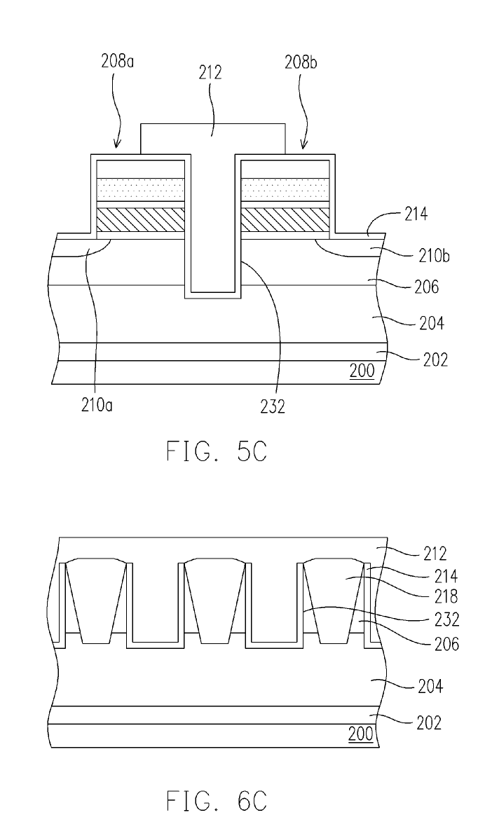

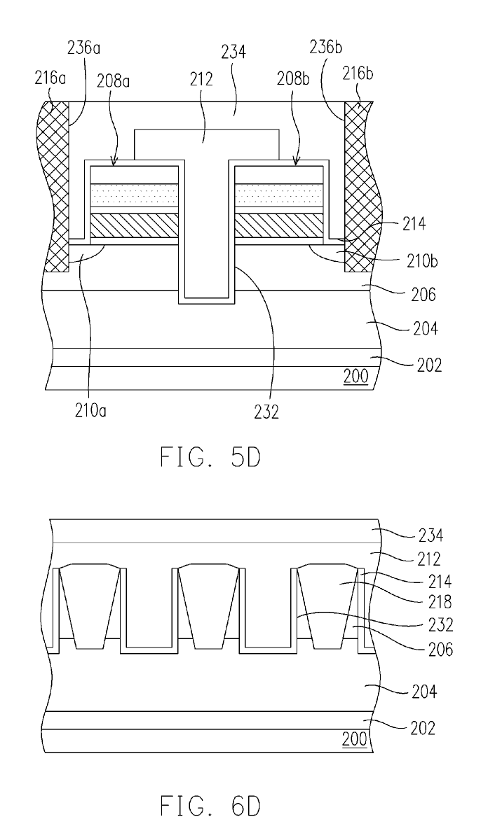

FIG. 5A through 5 D are schematic cross-sectional views along line I-I′ (the X direction) in FIG. 2 showing the steps for fabricating a non-volatile memory. FIG. 6A through 6D are schematic cross-sectional views along line II-II′ (the Y direction) in FIG. 2 showing the steps for fabricating a non-volatile memory. First, as shown in FIGS. 2, 5A and 6A, an n-type substrate 200 such as a silicon substrate is provided. Then, at least two isolation structures 218 are formed in the substrate 200 to define an active region 220. The isolation structures 218 are formed, for example, by performing a conventional shallow trench isolation (STI) process.

A p-type deep well 202 is formed in the substrate 200, for example, by implanting p-type dopants in an ion implantation process. Thereafter, an n-type well 204 is formed in the p-type deep well 202, for example, by implanting n-type dopants in an ion implantation process. Then, a p-type shallow well 206 is formed in the n-type well 204. The p-type shallow well 206 is formed, for example, by implanting p-type dopants in an ion implantation process.

As shown in FIGS. 2, 5B and 6B, at least a pair of stack gate structures 208a , 208b is formed in the active region 220 on the substrate 200. The stack gate structures 208a, 208b are located beside the isolation structures 218. Each of the stack gate structures 208a, 208b includes a tunneling layer 222, a floating gate layer 224, an inter-gate dielectric layer 226 and a control gate layer 228 sequentially formed on the substrate 200. The stack gate structures 208a, 208b are formed, for example, by performing a thermal oxidation process to form a tunneling material layer (not shown) on the substrate 200. Then, a plurality of floating gate material layer (not shown) is formed along the direction of extension (the X direction) of the isolation structures 218. The floating gate material layer is fabricated using polysilicon, doped polysilicon or other suitable material, for example. Thereafter, an inter-gate dielectric material layer (not shown) is formed on the floating gate material layer. The inter-gate dielectric material layer is a silicon oxide layer or an oxide/nitride/oxide composite stack layer. After that, a plurality of control gate layers 228 is formed in a direction perpendicular to the direction of extension of the isolation structures 218 (the Y direction). The control gate layers 228 are fabricated using polysilicon, doped polysilicon or other suitable material, for example. Furthermore, the control gates 228 is patterned out through a set of linear mask layers 230 that also extends in the same direction as the control gate layers 228. Next, the inter-gate dielectric material layer, the floating gate material layer and the tunneling material layer that are not covered by the control gate layer 228 are removed to form the stack gate structures 208a and 208b.

A pair of n-type drain regions 210a, 210b is formed in the p-type shallow well 206 outside the stack gate structures 208a and 208b. The n-type drain regions 210a, 210b are formed, for example, by forming a mask layer (not shown) between the stack gate structures 208a and 208b to cover the region between the two stack gate structures 208a, 208b. Thereafter, using the mask layer and the stack gate structures 208a, 208b as an implant mask, n-type dopants are implanted followed by performing a thermal diffusion process.

As shown in FIGS. 2, 5C and 6C, a portion of the substrate 200 between the two stack gate structures 208a, 208b is removed to form an opening 232. The bottom of the opening 232 is lower than the bottom of the p-type shallow well 206. Since the substrate 200 and the isolation structures 218 have different material properties, a self-aligned etching operation can be used in the process of removing a portion of the substrate 200. Furthermore, the opening 232 is located between two adjacent isolation structures 218.

Thereafter, a gate dielectric layer 214 is formed over the stack gate structures 208a, 208b and the exposed substrate 200. The gate dielectric layer is formed, for example, by performing a thermal oxidation process.

After that, an auxiliary gate layer 212 is formed on the gate dielectric layer 214 between the two stack gate structures 208a, 208b. The auxiliary gate layer 212 fills the opening 232 between adjacent isolation structures 218. The auxiliary gate layer 212 is fabricated using polysilicon, doped polysilicon or other suitable material. The method of fabricating the auxiliary gate layer includes forming an auxiliary gate material layer (not shown) over the substrate 200. Thereafter, a photolithographic and etching process is performed to pattern out a plurality of auxiliary gate layers 212 extending in a direction perpendicular to the isolation structures 218 (the Y direction).

As shown in FIGS. 2, 5D and 6D, a dielectric layer 234 is formed on the substrate 200 to cover the auxiliary gate layer 212 and the gate dielectric layer 214. The dielectric layer 234 has at least two contact openings 236a, 236b. The contact opening 236a exposes the drain region 210a and a portion of the p-type shallow well 206 and the contact opening 236b exposes the drain region 210b and a portion of the p-type shallow well 206. The dielectric layer 234 is fabricated from silicon oxide, silicon oxynitride or other suitable material, for example. The dielectric layer 234 is formed, for example, by depositing dielectric material and then performing a photolithographic and etching process to pattern out the contact openings 236a and 236b.

A plurality of conductive plugs 216a, 216b is formed inside the respective contact openings 236a and 236b. The conductive plug 216a is electrically connected to the drain region 210a and the p-type shallow well 206 and the conductive plug 216b is electrically connected to the drain region 210b and the p-type shallow well 206. Furthermore, the conductive plugs 216a and 216b are fabricated using tungsten or other suitable conductive material. The conductive plugs 216a, 216b are formed, for example, by depositing conductive material into the contact openings 236a, 236b and then performing a chemical-mechanical polishing operation or an etching back operation to remove redundant conductive material outside the contact openings 236a and 236b.

In the method of fabricating the non-volatile memory according to the present invention, the auxiliary gate layer can be used to trigger the source region. Hence, a suitable auxiliary gate voltage can be used to prevent the triggering of the source in a programming operation and thus resolving the device current leakage problem. Furthermore, the method of fabricating the non-volatile memory in the present invention is compatible with the conventional fabrication method. Thus, there is no need to acquire additional equipment.

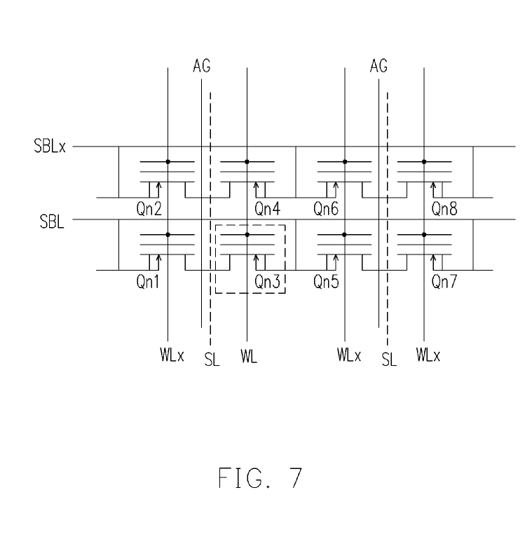

In the following, the various operating modes including the programming mode, the erasing mode and the reading mode of the aforementioned NOR type non-volatile memory are described. FIG. 7 is an equivalent circuit diagram of a NOR type memory cell array according to the present invention. Table 1 below registers the applied voltages for proceeding with various actual operations. However, the values stated in Table 1 serve only as a reference only and hence should not limit the scope of the present invention.

TABLE 1

| | Programming | | Reading |
|---|---|---|---|
| | Mode | Erasing Mode | Mode |
| Selected Word Line WL | −10V | 10V | 3.3V |
| Non-selected Word | −2V | 10V | 0V |
| Line WLₓ | | | |
| Selected Bit Line SBL | 6V | Floating (F) | 0V |
| Non-selected Bit line | 0V | Floating (F) | Floating (F) |
| SBLₓ | | | |
| Source Line SL | 6V | −6V | 1.65V |
| (n-type well 204) | | | |
| Auxiliary Gate Line AG | 0V | Floating (F) | 3.3V |
| p-type Deep Well (202) | 0V | −6V | 0V |

A plurality of memory cells Qₙ₁˜Qₙ₈ aligned to form a 4×2 array is shown in FIG. 7. FIG. 7 also shows the selected word line WL and the non-selected word line WLₓ that connect with the control gate layer of the memory cells in the vertical (column) direction. In the present embodiment, the selected word line WL connects the control gate layers of the memory cells Qₙ₃ and Qₙ₄ in the same column. The non-selected word line WLₓ connects the control gate layer of the memory cell Qₙ₁ and Qₙ₂ (or the memory cell Qₙ₅ and Qₙ₆, the memory cell Qₙ₇ and Qₙ₈) in the same column. Furthermore, the source line SL connect the first conductive type well (for example, the n-type well 204) of the memory cells in the same column and adjacent pair of memory cells in the horizontal (row) direction use the same source line SL. In the present embodiment, the source line SL connects the first conductive type well of the memory cells Qₙ₃ and Qₙ₄ in the same column and the two adjacent memory cells Qₙ₁ and Qₙ₃ in the same row use the same first conductive type well. The auxiliary gate line AG connects the auxiliary gate layer of the memory cells in the same column and the two adjacent memory cells in the horizontal (row) direction use the same auxiliary gate line AG. In the present embodiment, the auxiliary gate line AG connects the auxiliary gate layer of the memory cells Qₙ₃ and Qₙ₄ in the same column and the two adjacent memory cells Qₙ₁ and Qₙ₃ in the same row use the same auxiliary gate line AG. The selected bit line SBL and the non-selected bit line SBLₓ connect the drain region of memory cells in the same row. In the present embodiment, the selected bit line SBL connects the drain region of the memory cells Qₙ₁, Qₙ₃, Qₙ₅ and Qₙ₇ in the same row and the non-selected bit line SBLₓ connects the drain region of the memory cells Qₙ₂, Qₙ₄, Qₙ₆ and Qₙ₈ in the same row.

As shown in FIGS. 4, 7 and Table 1, the method of programming the non-volatile memory of the present invention includes applying a first voltage to the control gate 228 of the selected memory cell (for example, 208b in FIG. 4 and Qₙ₃ in FIG. 7). In addition, a second voltage is applied to the drain region 210b beside the selected memory cell and the n-type well 204 and a third voltage is applied to the auxiliary gate layer 212 and the p-type deep well 202. Thus, electric charges discharge from the floating gate layer 224 due to F-N tunneling. During programming, a fourth voltage is applied to control gate layer of the adjacent two memory cells. In addition, a fifth voltage is applied to the bit line (the drain region) of adjacent memory cells. In one preferred embodiment, the first voltage is between −5V to −15V, the second voltage is between 1V to 10V, the third voltage is about 0V and the fourth voltage is between −1V to −10V. In the present embodiment, the first voltage is −10V, the second voltage is 6V, the third voltage is 0V, the fourth voltage is −2V and the fifth voltage is 0V, for example.

Since the non-volatile memory in the present can use the auxiliary gate layer to trigger the source, a suitable auxiliary gate voltage can be used to prevent the triggering of the source in a programming operation. Therefore, the selection of the desired memory cell has no effect on adjacent memory cells so that the reliability of the device is improved. In addition, there is no device current leakage problem in the present invention.

The method of erasing data from the non-volatile memory of the present invention includes applying a sixth voltage to the control gate 228 of the selected memory cell (for example, 208b in FIG. 4 and Qₙ₃ in FIG. 7). Furthermore, a seventh voltage is applied to the n-type well 204 and the p-type deep well 202 and the drain region 210b beside the selected memory cell and the auxiliary gate layer 212 are set to a floating state. Hence, electric charges can be injected into the floating gate layer 224 due to F-N tunneling. During the erasing operating, a voltage identical to the voltage applied to the control gate layer of the selected memory cell is also applied to the control gate of an adjacent memory cell. Moreover, the bit line (the drain region) of the adjacent memory cell is set to a floating state. In one preferred embodiment, the sixth voltage is between 5 to 15 V and the seventh voltage is between −5V to −15V. In the present embodiment, the sixth voltage is 10V and the seventh voltage is −6V, for example.

The method of reading data from the non-volatile memory of the present invention includes applying an eighth voltage to the control gate 228 of the selected memory cell (for example, 208b in FIG. 4 and Qn3 in FIG. 7) and the auxiliary gate layer 212. Furthermore, a ninth voltage is applied to the n-type well 204 and a tenth voltage is applied to the drain region 210b beside the selected memory cell and the p-type deep well 202 to read the data stored in the memory cell. During the reading operation, an eleventh voltage is applied to the control gate of an adjacent memory cell and the bit line (the drain region) of the adjacent memory cell is set to a floating state. In one preferred embodiment, the eighth voltage is between 1V to 10V, the ninth voltage is between 1 V to 10V, the tenth voltage is about 0V and the eleventh voltage is about 0V. In the present embodiment, the eighth voltage is 3.3V, the ninth voltage is 1.65V, the tenth voltage is 0V and the eleventh voltage is 0V, for example.

Although no source region is disposed in the memory cell of the present invention, the source region can still be triggered by applying a voltage to the auxiliary gate layer. The voltage applied to the auxiliary gate layer produces a source inversion layer, also called a virtual source line. With the virtual source line in place, data can be read from the memory cell.

In the present invention, a suitable auxiliary gate voltage can be applied to prevent the triggering of a source during a programming operation. Hence, the conventional device current leakage problem is resolved and an adjacent memory cell is no longer affected by the memory cell selection. On the other hand, a virtual source line can be produced to carry out a reading operation simply by applying a voltage to the auxiliary gate layer.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A non-volatile memory, comprising:
a substrate;
a first conductive type well disposed in the substrate;
a second conductive type shallow well disposed in the first conductive type well;
a pair of stack gate structures disposed on the substrate, wherein each stack gate structure comprises at least a floating gate layer and a control gate layer above the floating gate layer;
two first conductive type drain regions disposed in the second conductive type shallow well outside the pair of stack gate structures;
an auxiliary gate layer disposed on the substrate between the two stack gate structures and extending down to pass through a portion of the substrate, wherein the bottom of the auxiliary gate layer is below the bottom of the second conductive type shallow well;
a gate dielectric layer disposed at least between the auxiliary gate layer and the substrate and between the auxiliary gate layer and the stack gate structures; and
at least two conductive plugs disposed on the substrate and extending down to connect with the second conductive type shallow well and the drain region therein.

2. The non-volatile memory of claim 1, wherein the substrate is a first conductive type substrate.

3. The non-volatile memory of claim 1, further comprises a second conductive type deep well disposed in the substrate such that the first conductive type well is located inside the second conductive type deep well.

4. The non-volatile memory of claim 1, wherein each stack gate layer comprises a tunneling layer, the floating gate layer, an inter-gate dielectric layer and the control gate layer sequentially stacked on the substrate.

5. The non-volatile memory of claim 1, wherein the material constituting the auxiliary gate layer, the floating gate layer and the control gate layer comprises polysilicon or doped polysilicon.

6. The non-volatile memory of claim 1, wherein the material constituting the gate dielectric layer comprises silicon oxide.

7. The non-volatile memory of claim 1, wherein the non-volatile memory is a NOR type memory array.

8. The non-volatile memory of claim 1, wherein the first conductive type is n-type and the second conductive type is p-type.

9. The non-volatile memory of claim 1, further comprising a plurality of isolation structures disposed in the substrate to define an active region, wherein the pair of the stack gate structures is disposed on the substrate within the active region beside the isolation structures.

10. The non-volatile memory of claim 9, wherein the auxiliary gate layer is disposed between adjacent pair of isolation structures.

11. A method of fabricating a non-volatile memory, comprising:
providing a substrate;
forming a first conductive type well in the substrate;
forming a second conductive type shallow well in the first conductive type well;
forming at least a pair of stack gate structures on the substrate, wherein each stack gate structure comprises at least a floating gate layer and a control gate layer above the floating gate layer;
forming two first conductive type drain regions in the second conductive type shallow well outside the pair of stack gate structures;
removing a portion of the substrate between the two stack gate structures to form an opening in the substrate, wherein the bottom of the opening is below the bottom of the second conductive type shallow well;
forming a gate dielectric layer over the stack gate structures and the exposed substrate;
forming an auxiliary gate layer on the gate dielectric layer between the two stack gate structures to fill the opening;
forming a dielectric layer over the substrate to cover the gate dielectric layer and the auxiliary gate layer such that the dielectric layer has at least two contact openings, wherein each contact opening exposes the drain region and a portion of the second conductive type shallow well; and
forming a plurality of conductive plugs inside the contact openings.

12. The method of claim 11, wherein the step of removing a portion of the substrate between the two stack gate structures comprises performing a self-aligned etching process.

13. The method of claim 11, wherein the substrate is a first conductive type substrate.

14. The method of claim 1 1, wherein after providing the substrate but before forming the first conductive type well in the substrate, the method further comprises forming a second conductive type deep well in the substrate such that the first conductive type well is located inside the second conductive type deep well.

15. The method of claim 11, wherein each stack gate structure comprises a tunneling layer, the floating gate layer, a gate dielectric layer and the control gate layer sequentially stacked on the substrate.

16. The method of claim 11, wherein the material constituting the auxiliary gate layer, the floating gate layer and the control gate layer comprises polysilicon or doped polysilicon.

17. The method of claim 11, wherein each conductive plug is electrically connected to the drain region and the second conductive type shallow well.

18. The method of claim 11, wherein the first conductive type is n-type and the second conductive type is p-type.

19. The method of claim 11, wherein after providing the substrate but before forming the first conductive well in the substrate, the method further comprises forming a plurality of isolation structures in the substrate to define an active region such that the pair of stack gate structures is formed on the substrate within the active region beside the isolation structures.

20. The method of claim 19, wherein the auxiliary gates layer is formed between adjacent pairs of isolation structures.

21. A method of operating a non-volatile memory, wherein the non-volatile memory comprises a substrate, a first conductive type well disposed in the substrate, a second conductive type shallow well disposed in the first conductive type well, a pair of stack gate structures disposed on the substrate such that each stack gate structure comprises a floating gate layer and a control gate layer above the floating gate layer, two first conductive type drain regions disposed in the second conductive type shallow well outside the pair of stack gate structures, an auxiliary gate layer disposed on the substrate between the two stack gate structures and extending down to pass through a portion of the substrate such that the bottom of the auxiliary gate layer is below the bottom of the second conductive type shallow well; the operating method comprising:
selecting one as a selected memory cell in the pair of stack gate structures; and
when performing a programming operation, applying a first voltage to the control gate layer of the selected memory cell, applying a second voltage to the drain region beside the selected memory cell and the first conductive type well, and applying a third voltage to the auxiliary gate layer and the second conductive type deep well to program data into the selected memory cell.

22. The operating method of claim 21, wherein the first voltage is between −5V to −15V, the second voltage is between 1V to 10V and the third voltage is about 0V.

23. The operating method of claim 21, further comprising:
when performing an erasing operation, applying a fourth voltage to the control gate layer of the selected memory cell, applying a fifth voltage to the first conductive type well and the second conductive type deep well and setting the drain region beside the selected memory cell and the auxiliary gate layer into a floating state to erase the data within the selected memory cell.

24. The operating method of claim 23, wherein the fourth voltage is between 5V to 15V and the fifth voltage is between −5V to −15V.

25. The operating method of claim 21, further comprising:
when performing a reading operation, applying a sixth voltage to the control gate layer and the auxiliary gate layer of the selected memory cell, applying a seventh voltage to the first conductive type well and applying an eighth voltage to the drain region beside the selected memory cell and the second conductive type deep well to read data from the selected memory cell.

26. The operating method of claim 25, wherein the sixth voltage is between 1V to 10V, the seventh voltage is between 1V to 10V and the eighth voltage is about 0V.
